(19) United States
(12) Patent Application Publication
(10) Pub. No.: US 2010/0103616 A1
(43) Pub. Date: Apr. 29, 2010

(54) ELECTRONIC DEVICE WITH CENTRIFUGAL FAN

(75) Inventors: CHING-BAI HWANG, Tu-Cheng (TW); ZHI-HUI ZHAO, Shenzhen City (CN); JUI-WEN HUNG, Tu-Cheng (TW); PO-HSUAN KUO, Tu-Cheng (TW)

Correspondence Address: PCE INDUSTRY, INC.;ATT. Steven Reiss, 288 SOUTH MAYO AVENUE, CITY OF INDUSTRY, CA, 91789, US

(73) Assignees: FURUI PRECISE COMPONENT (KUNSHAN) CO., LTD., KunShan (CN); FOXCONN TECHNOLOGY CO., LTD., Tu-Cheng (TW)

(21) Appl. No.: 12/469,674

(22) Filed: May 20, 2009

(30) Foreign Application Priority Data
Oct. 28, 2008 (CN) 200810305259.1

(51) Int. Cl. H05K 7/20

(52) U.S. Cl. 361/695

(57) ABSTRACT

An electronic device includes a shell and a centrifugal fan. The shell includes a top wall, a bottom wall parallel to the top wall, and a sidewall perpendicular to the top wall and the bottom wall. The centrifugal fan is arranged between the top wall and the bottom wall. The centrifugal fan defines a first inlet facing the top wall and a second inlet facing the bottom wall. The first inlet and the second inlet are slantwise to the top wall and the bottom wall of the shell.

### BACKGROUND

1. Technical Field

The disclosure generally relates to electronic devices, and particularly to an electronic device incorporating a centrifugal fan.

2. Description of Related Art

With continuing development of the electronic technology, electronic components such as CPUs are generating more and more heat which is required to be dissipated immediately. Cooling fans are commonly used in combination with heat sinks for cooling the electronic components. Since most of electronic devices that contain electronic components therein, such as a laptop computer, do not have enough space therein, a centrifugal fan which requires only a small space for installation is generally used.

The centrifugal fan includes a casing and an impeller received in the casing. The casing defines a pair of air inlets at top and bottoms sides, and an air outlet at a lateral side thereof. The air outlet is perpendicular to the air inlets. In use, the impeller rotates continuously to generate an airflow from the air inlets towards the electronic component via the air outlet, thus to cool the electronic component. However, generally, the centrifugal fan is arranged in the electronic device with the air inlets thereof parallel to a housing of the electronic device. A narrow clearance is thus defined between each of the air inlets and the housing for air flowing into the centrifugal fan and then to the air outlet, which decreases an amount of the airflow of the centrifugal fan and finally influences a heat dissipation of the electronic components.

For the foregoing reasons, therefore, there is a need in the art for an electronic device incorporating a centrifugal fan which overcomes the limitations described.

### BRIEF DESCRIPTION OF THE DRAWINGS

FIG. 1 is a schematic view of an electronic device according to an exemplary embodiment.

FIG. 2 is an exploded view of a heat dissipation module of the electronic device of FIG. 1.

FIG. 3 is an assembled view of the heat dissipation module of FIG. 2.

FIG. 4 is a schematic view of an electronic device according to an alternative embodiment.

### DETAILED DESCRIPTION

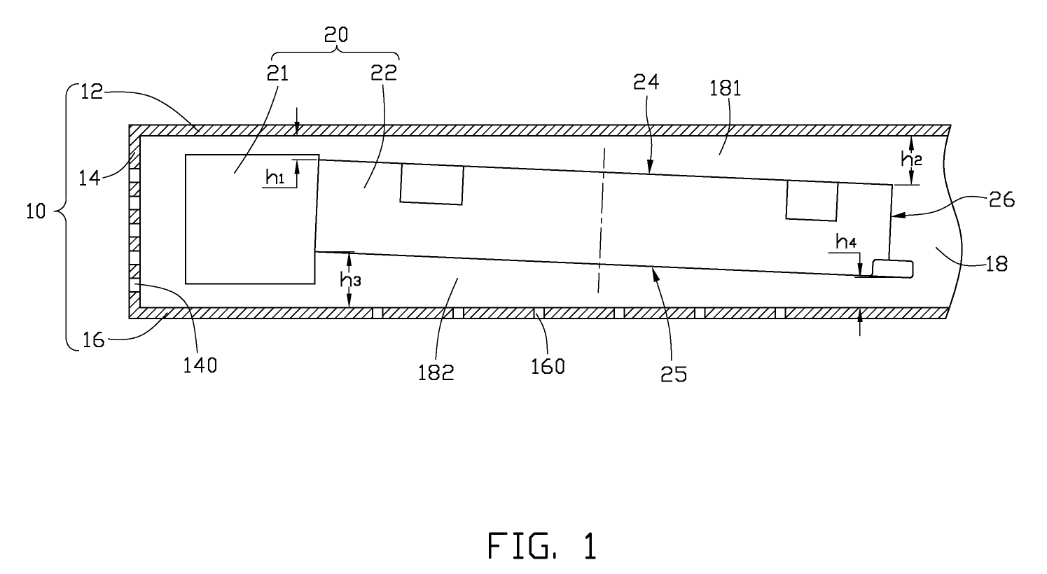

Referring to FIG. 1, an electronic device according to an exemplary embodiment includes a shell 10 incorporating electronic components (not shown) therein, and a heat dissipation module 20 received in the shell 10 for dissipating heat generated by the electronic components.

The shell 10 includes a top wall 12, a bottom wall 16, and a sidewall 14 interconnecting the top wall 12 and the bottom wall 16. The top wall 12 and the bottom wall 16 are parallel to each other. The sidewall 14 is perpendicular to the top wall 12 and the bottom wall 16. Cooperatively the top wall 12, the bottom wall 16, and the sidewall 14 define a space 18 in the electronic device. A plurality of ventilating holes 140 are defined in the sidewall 14. A plurality of apertures 160 are defined in the bottom wall 16 of the shell 10. Alternatively, the plurality of apertures 160 can be defined in the top wall 12 of the shell 10. The apertures 160 and the ventilating holes 140 intercommunicate the space 18 in the electronic device and an outside.

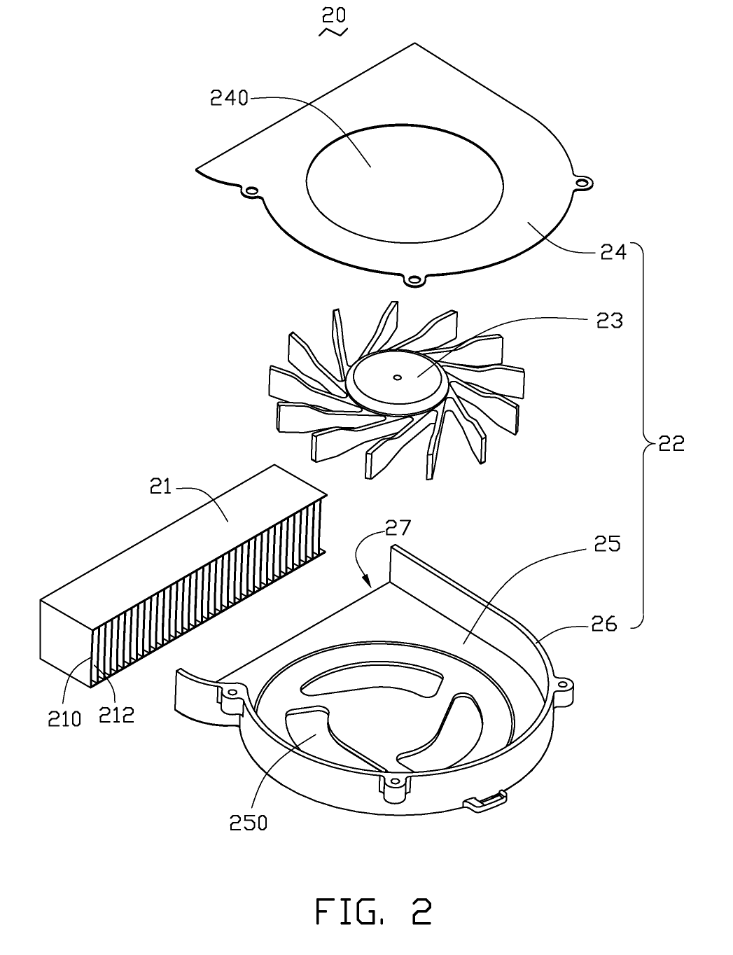

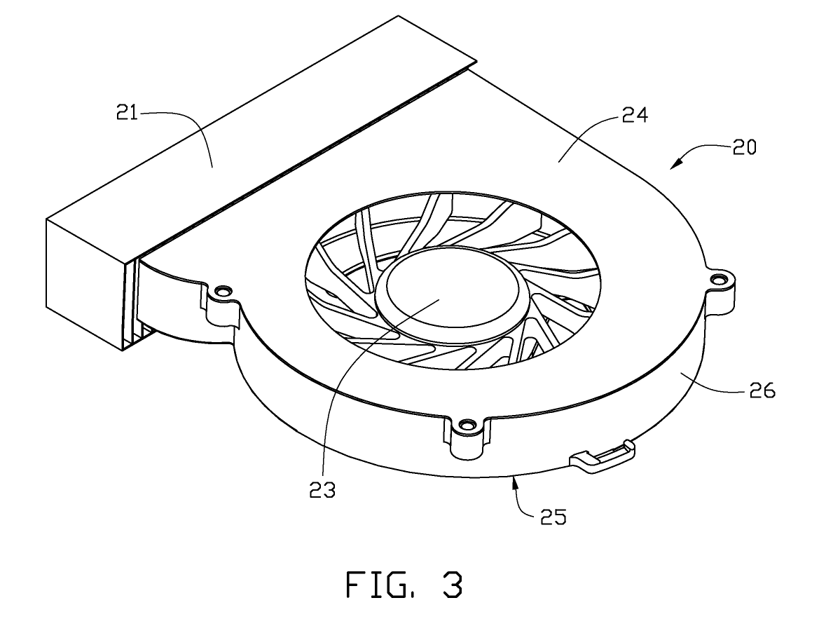

Referring to FIGS. 2 and 3, the heat dissipation module 20 is received in the space 18, and includes a centrifugal fan 22 and a fin unit 21. The centrifugal fan 22 includes a fan housing and an impeller 23. The fan housing includes a top plate 24, a bottom plate 25 and a side plate 26. The top plate 24 and the bottom plate 25 are substantially arch-shaped, and are parallel to each other. The side plate 26 integrally extends from an outer periphery of the bottom plate 25 to the top plate 24, and is perpendicular to the top plate 24 and the bottom plate 25. Cooperatively the top plate 24, the bottom plate 25 and the side plate 26 defines a room receiving the impeller 23.

A first inlet 240 is defined at a central portion of the top plate 24, and a second inlet 250 is defined around a central portion the bottom plate 25. A center of the first inlet 240 and a center defined by the second inlet 250 are coaxial with a center of with the impeller 23. An outlet 27 is defined in the side plate 26 perpendicular to the first inlet 240 and the second inlet 250. The fin unit 21 is arranged at the air outlet 27 of the centrifugal fan 22. The fin unit 21 includes a plurality of fins 210 stacked together. A channel 212 is defined between two neighboring fins 210. The air channels 212 communicate with the air outlet 27 of the centrifugal fan 22.

Referring to FIG. 1 again, after assembled into the electronic device, the fin unit 21 is arranged adjacent to the sidewall 14 of the shell 10 and faces the ventilating holes 140. The centrifugal fan 22 is arranged between the top wall 12 and the bottom wall 16, and is slightly aslant with a left side adjacent to the fin unit 21 higher than a right side away from the fin unit 21. An upper gap 181 is defined between the top wall 12 of the shell 10 and the top plate 24 of the centrifugal fan 22, and a lower gap 182 is defined between the bottom wall 16 of the shell 10 and the bottom plate 25 of the centrifugal fan 22. A height of the upper gap 181 increases gradually in a left to right direction, whilst a height of the lower gap 182 decreases gradually in the left to right direction.

More specifically, the space 18 of the shell 10 has a height being about 16.6 mm and the centrifugal fan 22 has a height being about 12.6 mm. In other words, the height of the space 18 is about 4 mm larger than the height of the centrifugal fan 22. The upper gap 181 at the left side has a height h1 of about 1.1 mm, whilst the upper gap 181 at the right side of the centrifugal fan 22 has a height h2 of about 2.9 mm. A height h3 of the lower gap 182 at the left side of the centrifugal fan 22 is about 2.9 mm, whilst a height h4 of the lower gap 182 at the right side of the centrifugal fan 22 is about 1.1 mm. During operation, the impeller 23 of the centrifugal fan 22 rotates to generate forced airflow. The airflow flows into the centrifugal fan 22 via both of the first inlet 240 and the second inlet 250, and then flows through the air outlet 27 to the fin unit 21 to take away the heat absorbed by the fin unit 21 from the electronic components, and finally the heated airflow after across the fin unit 21 flows to the outside via the ventilating holes 140 of the sidewall 14 of the shell 10.

In such an electronic device which incorporates an aslant centrifugal fan 22 therein, a volumetric flow rate of the airflow is about 2.81 CFM. However, if the centrifugal fan 22 is arranged horizontally as the conventional electronic devices, a volumetric flow rate of the airflow is about 2.65 CFM. Thus, the volumetric flow rate of the airflow of the present electronic device is increased for about 6 percent. Finally, a heat dissipation efficiency of the heat dissipation module 20 is enhanced, and the electronic component of the electronic device can have a lower working temperature. Such an arrangement of centrifugal fan is more suitable for the electronic devices do not have enough space, usually a space for accommodating the centrifugal fan with a height exceeding that of the centrifugal fan no larger than 5 mm. Preferably, a difference of the height of the space and the height of the centrifugal fan is not larger than 3 mm.

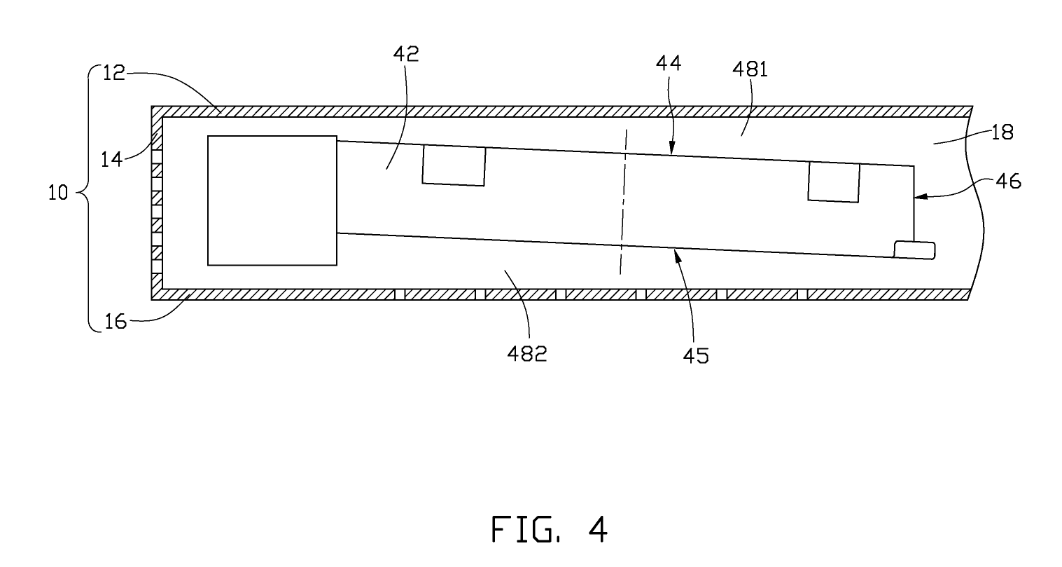

Referring to FIG. 4, an electronic device in accordance an alternative embodiment is shown. The difference between this electronic device and the previous electronic device is in the centrifugal fan 42. In this embodiment, the centrifugal fan 42 includes a top plate 44, a bottom plate 45, and a side plate 46. The top plate 44 and the bottom plate 45 are parallel to each other, whilst the side plate 46 is slantwise. An acute angle is defined between the bottom plate 45 and the side plate 46 in the centrifugal fan 42, whilst an obtuse angle is defined between the top plate 44 and the side plate 46 in the centrifugal fan 42. After assembled into the space 18 of the shell 10, the top plate 44 and the bottom plate 45 of the centrifugal fan 42 slant from upper left to lower right, and the side plate 46 is vertical, i.e., perpendicular to top and bottom walls 12, 16 of the electronic device and parallel to the sidewall 14. An upper gap 481 is defined between the top plate 44 and the top wall 12 of the shell 10 with a height increasing from a left side to a right side, and a lower gap 482 is defined between the bottom plate 45 and the bottom wall 16 of the shell 10 with a height decreasing from the left side to the right side.

It is to be understood, however, that even though numerous characteristics and advantages of the disclosure have been set forth in the foregoing description, together with details of the structure and function of the disclosure, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. An electronic device, comprising:
a shell comprising a top wall, a bottom wall parallel to the top wall, and a sidewall perpendicular to the top wall and the bottom wall and interconnecting the top wall and the bottom wall; and
a centrifugal fan arranged between the top wall and the bottom wall, the centrifugal fan defining a first inlet facing the top wall and a second inlet facing the bottom wall, the first inlet and the second inlet being slantwise to the top wall and the bottom wall of the shell.

2. The electronic device of claim 1, wherein the centrifugal fan comprises a bottom plate, a top plate, and a side plate interconnecting the bottom plate and the top plate, the first inlet being defined in the top plate, and the second inlet being defined in the bottom plate.

3. The electronic device of claim 2, wherein the top plate is parallel to the bottom plate, and the side plate is perpendicular to the top plate and the bottom plate.

4. The electronic device of claim 2, wherein the top plate is parallel to the bottom plate, and the side plate is slantwise to the top plate and the bottom plate.

5. The electronic device of claim 4, wherein the side plate is parallel to the sidewall of the shell.

6. The electronic device of claim 4, wherein an acute angle is defined between the bottom plate and the side plate in the centrifugal fan, whilst an obtuse angle is defined between the top plate and the side plate in the centrifugal fan.

7. The electronic device of claim 2, wherein a difference of a distance between the top wall and the bottom wall of the shell and a height of the centrifugal fan is not larger than 5 mm.

8. The electronic device of claim 2, wherein a difference of a distance between the top wall and the bottom wall of the shell and a height of the centrifugal fan is not larger than 3 mm.

9. The electronic device of claim 2, wherein a plurality of ventilating holes are defined in the sidewall of the shell, the centrifugal fan defining an air outlet in the side plate facing the ventilating holes.

10. The electronic device of claim 9, further comprising a fin unit arranged at the air outlet of the centrifugal fan.

11. An electronic device, comprising:
a shell comprising a first wall and a second wall parallel to the first wall;
a centrifugal fan arranged between the first wall and the second wall of the shell, comprising a first plate, a second plate, and a side plate interconnecting the first plate and the second plate, the first plate adjacent to the first wall and defining a first inlet therein, the second plate adjacent to the second plate and defining a second inlet therein, an outlet being defined in the side plate, a gap defined between the first wall and the first plate having a height increasing from a side of the centrifugal fan forming the outlet to a side of the centrifugal fan remote from the outlet.

12. The electronic device of claim 11, wherein another gap is defined between the second wall and the second plate, and has a height decreasing from the side of the centrifugal fan forming the outlet to the side of the centrifugal fan remote from the outlet.

13. The electronic device of claim 12, wherein the height of the gap between the first wall and the first plate changes from 1.1 mm to 2.9 mm, and the height of the gap between the second wall and the second plate changes from 2.9 mm to 1.1 mm.

14. The electronic device of claim 11, wherein the top plate is parallel to the bottom plate, and the side plate is perpendicular to the top plate and the bottom plate.

15. The electronic device of claim 11, wherein the top plate is parallel to the bottom plate, and the side plate is slantwise to the top plate and the bottom plate.

16. The electronic device of claim 15, wherein the side plate is perpendicular to the top wall of the shell.
